(19) United States
(12) Patent Application Publication
(10) Pub. No.: US 2026/0164596 A1
(43) Pub. Date: Jun. 11, 2026

(54) Cabinet with internal heat dissipation system

(71) Applicant: Fi.Mo.Tec. S.p.A., Milano (IT)

(72) Inventors: Roberto Moscetta, Gallicano Nel Lazio (RM) (IT); Antonio Tony Caputo, Ciampino (RM) (IT)

(21) Appl. No.: 19/127,356

(22) PCT Filed: Nov. 14, 2023
(86) PCT No.: PCT/IB2023/061466

§ 371 Date: May 5, 2025

(30) Foreign Application Priority Data
Nov. 15, 2022 (IT) 102022000023523

(51) Int. Cl. H05K 7/20

(52) U.S. Cl. CPC H05K 7/20145; H05K 7/20172; H05K 7/20572; H05K 7/207

(57) ABSTRACT

A cabinet with an internal heat dissipation system includes wall, at least one of which is formed with a panel having a first slab arranged toward the inside of the cabinet and a second slab arranged towards the outside of the cabinet, a heat exchange corrugated septum being arranged between the first and the second slab. The corrugated septum delimits first vertical air circulation channels between the corrugated septum and the first slab and second vertical air circulation channels between the corrugated septum and the second slab. The first vertical air circulation channels are part of a first circuit circulating air inside the cabinet and the second vertical air circulation channels are part of a second circuit circulating air outside the cabinet.

The present invention relates to an innovative metal cabinet provided with an internal heat dissipation system. In particular, such a cabinet is preferably adapted to house electrical, electronic, chemical, physical or technological equipment in general, producing heat that must be transferred out of the cabinet.

The problem of extracting heat from inside cabinets containing heat-producing equipment is well known. A first solution is to provide the cabinet with large openings for passive air circulation between the inside and outside of the cabinet, but such a system often has limited and poor effectiveness. Cabinets have therefore also been proposed wherein heat exchangers with an even relatively complex internal and external design, forced air extraction systems, active air conditioning systems (chillers), etc. are used. All these systems are often rather bulky, both inside the cabinet and outside, and reduce the available space.

Systems providing for the extraction, whether forced or not, of hot air from the cabinet and replacement thereof with fresh air from outside also have the disadvantage of bringing the equipment installed in the cabinet into contact with the outside atmosphere, air that may contain various pollutants and contain for example dust, salt deposits, humidity, or other contaminants in general.

In the case of active systems such as air conditioners, in addition to their large size and complexity (they are often implemented with large centralised systems connected to several cabinets), they also require relatively high power for their operation and frequent and expensive maintenance.

The general object of the present invention is to overcome the drawbacks of the prior art and to provide a cabinet with an internal heat dissipation system that can be effective, space-saving, robust, relatively cost-effective, low-maintenance and that requires little energy for its operation.

In view of this object, a cabinet has been devised, according to the invention, with an internal heat dissipation system, characterised in that it comprises at least one of the walls formed with a panel comprising in turn a first slab arranged towards the inside of the cabinet and a second slab arranged more towards the outside of the cabinet and between which a heat exchange corrugated septum is present delimiting first vertical air circulation channels between the corrugated septum and the first slab and second vertical air circulation channels between the corrugated septum and the second slab, the first vertical channels being part of a first circuit circulating air inside the cabinet and the second vertical channels being part of a second circuit circulating air outside the cabinet.

To better explain the innovative principles of the present invention and the advantages thereof compared to the prior art, one possible illustrative embodiment applying such principles will be described below, with the aid of the attached drawings. In the drawings:

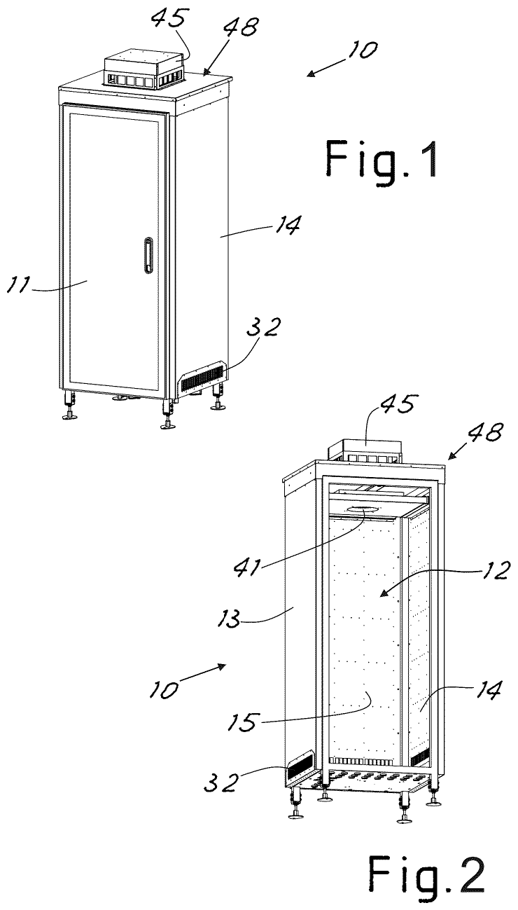

FIG. 1 represents a front perspective view of a cabinet made according to the invention;

FIG. 2 represents a view of the cabinet in FIG. 1 with an access door removed;

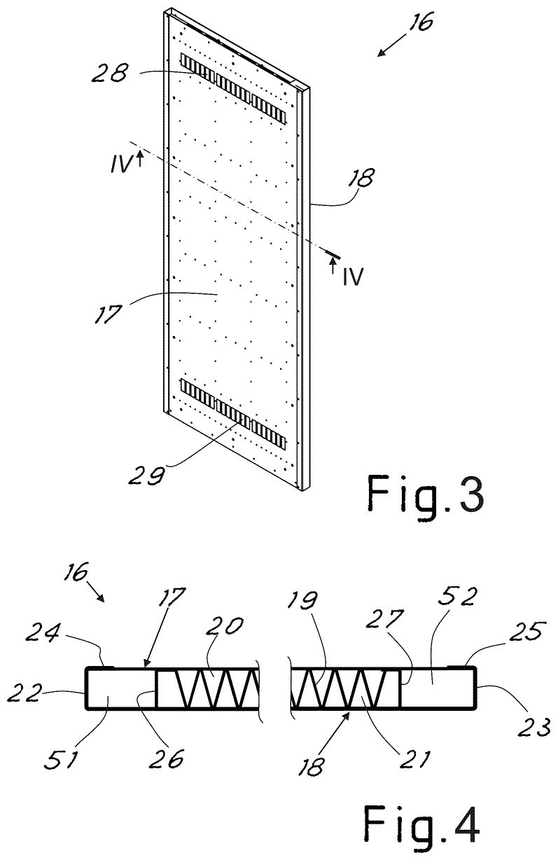

FIG. 3 represents a perspective view of a possible embodiment of a panel forming at least one wall of the cabinet in FIG. 1;

FIG. 4 represents a cross-section taken along the line IV-IV of FIG. 3;

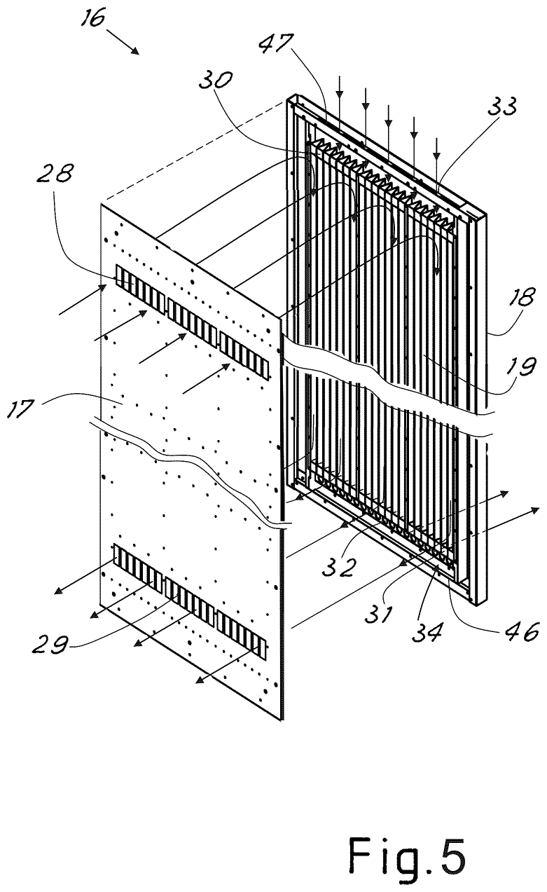

FIG. 5 represents a perspective and partially exploded view of the panel of FIG. 3;

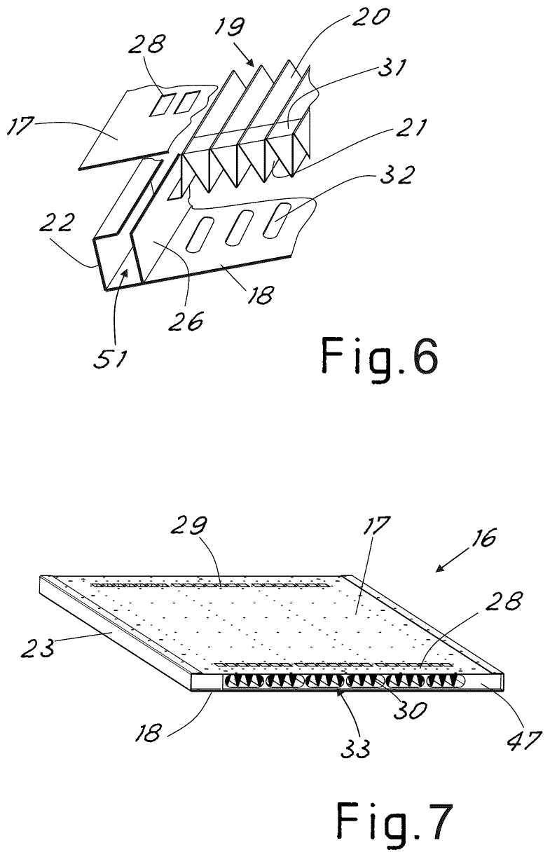

FIG. 6 is an exploded schematic and perspective view of an area of the panel in FIG. 3;

FIG. 7 represents a schematic perspective view taken from an upper end of the panel of FIG. 3;

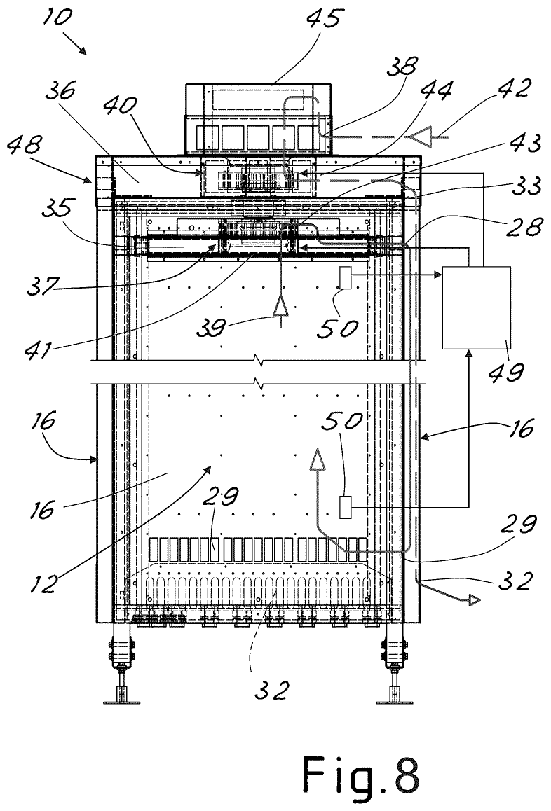

FIG. 8 represents a schematic side elevation view of a cabinet according to the invention with possible air circulation paths highlighted;

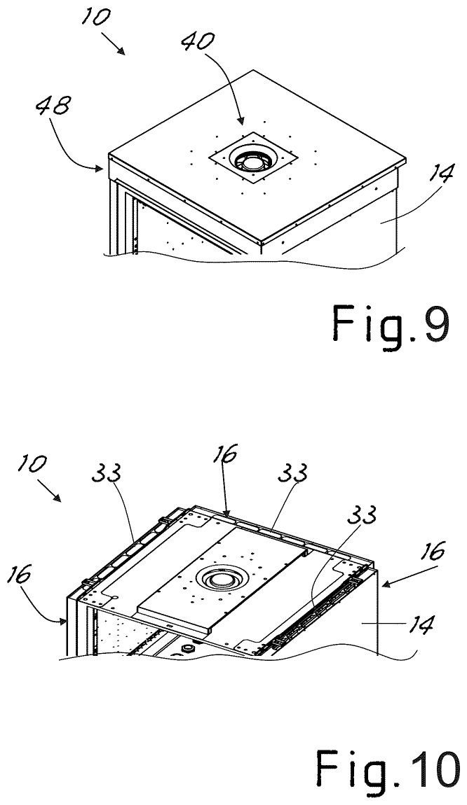

FIGS. 9 and 10 represent partial perspective views of a possible embodiment of an upper part of the cabinet of FIG. 1, with some parts of the upper cover removed.

With reference to the Figures, FIG. 1 shows a cabinet made according to the invention and globally referred to as 10. This cabinet 10 preferably has a parallelepiped shape with a front wall that can be opened to create a door 11 to access the internal space 12. This internal space 12, visible for example in FIG. 2, is adapted to house and protect, in the cabinet, elements (not shown, as they may be of any nature such as electrical, electronic, chemical, physical or technological equipment in general, etc.) that produce heat which must be dissipated by transferring it out of the cabinet.

As the person skilled in the art can easily imagine, the internal space 12 can be completely free or can house shelves, racks, guides, etc., depending on the specific requirements of what is to be housed in the cabinet. At least one of the cabinet walls (and, preferably, at least the rear wall 15 or at least the two side walls 13, 14, or also, advantageously, the side walls 13, 14 and the rear wall 15) comprises, or is formed entirely of, an air-to-air heat exchange panel according to the invention. A possible advantageous embodiment of such a panel is shown with reference to FIG. 3 and following ones.

According to this embodiment, the panel (generally referred to as 16) comprises on one face a first slab 17 and on the opposite face a second slab 18. These two slabs 17, 18 are advantageously made of metal material (e.g. steel or aluminium sheets) and have a thickness adapted to ensure, together with other elements of the structure, a desired strength of the cabinet walls.

When the panel makes up a cabinet wall, the first slab 17 is arranged towards the inside of the cabinet and the second slab 18 is arranged more towards the outside of the cabinet. Advantageously, the first slab 17 forms the internal surface of the corresponding cabinet wall, while the second slab 18 forms the external surface of the corresponding cabinet wall.

As visible from section IV-IV in FIG. 4, the two slabs 17, 18 are separated from each other by a corrugated septum 19 which is present between them to define first vertical channels 20 between the corrugated septum 19 and the first slab 17 and second vertical channels 21 between the septum 19 and the second slab 18.

The septum 19 is made of a material, advantageously metal, chosen with a suitably high thermal conductivity to achieve a desired passage of heat between the air in the first channels 20 and the air in the second channels 21. The septum 19 can advantageously be formed of a suitably shaped metal sheet. For example, the material chosen for the septum can be aluminium.

The septum 19 thus creates a septum exchanging heat between the air in the first channels 20 and the air in the second channels 21, as will become clear.

The corrugation of the septum 19 can be of various shapes to make vertical channels 20 and 21. In particular, in the embodiment shown, it is advantageously formed with a zig-zag shape with sharp edges to create channels 20 and 21 with a substantially triangular cross-section. This embodiment is advantageous as it is simple to produce, it has a good heat exchange and a satisfactory strength and rigidity of the panel. This does not exclude that an alternative corrugated shape could also be used. For example, a shape without sharp edges, e.g. sinusoidal or similar, can also be devised.

The septum 19 can also be made up of several distinct elements, such as shaped strips that are suitably placed side by side. For example, modular elements can be made with a given number of corrugations and which are placed side by side in the space between the slabs to form the entire septum 19.

As will be clear hereinafter, the panel 16 creates an air-to-air exchanger, with the first channels 20 being part of a first circuit 39 circulating air inside the cabinet, the second channels 21 being part of a second circuit 42 circulating air from outside the cabinet.

To assist, cause or control air circulation, appropriate circulation fans may also be comprised in one or both of the circuits 39 and 42, which may also, if desired, be assisted by a control circuit operating them according to the temperature to be maintained in the cabinet.

In particular, as will be further made clear hereinafter, the two air circulation circuits may comprise fans in a suitable position in the cabinet (e.g. preferably in the cabinet upper part or cap) to forcedly move air inside the cabinet so that it cyclically passes through the first channels 20 of the panel, and to suck air from outside the cabinet to forcedly circulate it through the second channels 21 and then re-emit it outside the cabinet, while still keeping the two circulation circuits separate.

As it can be seen in the section of FIG. 4, for example, the panel can advantageously have closed side edges 22 and 23 to increase the rigidity of the panel and allow it to be more easily fixed peripherally to make up the cabinet structure.

In order to create the two side edges 22, 23, for example, a vertical profile with a U-shaped or rectangular cross-section may be used, or one or both of the sheets 17, 18 may have side edges suitably bent and shaped to allow the slabs to be mutually attached to each other along these edges while maintaining the gap between them containing the corrugated septum 19.

For example, as it can be clearly seen in FIG. 4, a slab (in the case shown in the figures, the external slab 18) may have the two side edges folded to each make a U at which free end 24, 25 a corresponding flat side edge of the other slab is attached (internally or externally).

In any case, it may be advantageous to identify two areas 51 and 52 along the side edges that are closed according to two generic box-shaped profiles to provide, for example, additional structural rigidity to the panel and/or facilitate its assembly to form the cabinet. This also provides additional structural strength to the cabinet formed with the panels 16.

In addition, the two side areas 51 and 52 of the panel can be easily made isolated from the channels 20 and 21, and holes can be easily made therein to fix the panels to form the cabinet, or to fix accessories to the panel (e.g. guides or supports inside the cabinet) without worrying about the air circulation channels being drilled and the need for air-tight sealing.

Two bulkheads 26, 27 extending transversely between the two slabs 17 and 18 and parallel to the closed edges 22, 23 of the panel can be used to create these areas 51 and 52 separated from the channels. Such bulkheads 26, 27 can be formed in a single piece with the two side edges of the septum 19 or can be part of added profiles.

As it is clear from FIG. 4, the two areas 51 and 52 can also be formed with a special profile with a rectangular cross-section fixed on the edges of the panel between the two slabs 17 and 18.

As it can be seen, for example, in FIG. 3 and also in FIG. 5 (where the slab 17 is offset from the rest of the panel to schematically show the possible internal structure of the panel), in a possible advantageous embodiment of the air circulation system according to the invention the panel 16 may comprise on the first slab 17 first upper slots 28 and second lower slots 29 which are in communication with the first vertical channels 20 near an upper and a lower end of these channels 20 inside the panel, respectively.

The first and second slots 28, 29 are therefore respectively close to the upper and lower edges of the panel.

As it can be seen in FIG. 5, for example, the vertical length of the septum 19 can be shorter than the total height of the panel 16 in order to leave gaps in the panel above and below the septum 19 for the purposes that will become clear later.

As it can also be seen in FIG. 5, the channels 20 can be advantageously terminated at their upper and lower ends with plugs 30 and 31 (e.g. of plastic material) after the upper and lower slots 28, 29. The air flow, as schematically shown by the arrows, can enter through the upper slots 28, travel downwards through the vertical channels 20 and out from the lower slots 29, thus obtaining a corresponding part of the first air circulation circuit in the air-to-air exchanger. The plugs (e.g. made of plastic) can also be advantageously just fitted on the ends of the ducts.

The first slots 28 are intended to receive air from inside the cabinet to let it enter the upper end of the channels 20. The second slots 29 are intended to introduce this air back into the cabinet after it has passed through the channels 20.

As it can be seen, for example, in FIG. 5 and better in FIG. 6, advantageously the external slab 18 can itself have lower slots 32 facing the external side of the panel (i.e. to be on the outside of the cabinet as visible, for example, in FIG. 1). The channels 21 communicate at their lower end with the slots 32, advantageously underneath the plugs 31, which close the first channels 20 at the bottom. The communication can take place through an area 34 in the panel below the lower end of the channels 21 and where all the channels 21 terminate.

The panel 16 can have the edge or lower area closed so that the flow of air flowing downwards in the channels 21 can only exit through the slots 32. For example, the lower edge of the panel can have a closing and reinforcing wall 46 that is placed between the slabs 17 and 18. The wall 46 can, for example, be formed by a wall of a U-shaped profile fixed between the slabs, as visible in the figures and forming the lower edge of the panel. Alternatively, the lower edge can be closed after the panel has been mounted to form the cabinet.

The second channels 21 at their upper end, on the other hand, can be advantageously opened at the top in an area towards the upper edge of the panel, an area comprising upper passages 33, e.g. in the form of slots or holes cut side-by-side along an upper edge of the panel made from a reinforcing wall 47 and placed between the slabs. The wall 47 can, for example, be formed by a wall of a U-shaped profile fixed between the slabs along the upper edge of the panel, as shown in the figures.

As schematically shown by the arrows in FIG. 5, in the panel described an air flow can enter from the upper passages 33, travel downwards through the vertical channels 21 and exit through the lower slots 32, thus forming the corresponding part of the second air circulation circuit of the air-to-air exchanger.

All or some of the slots 28, 29, 32 may, for example, be made with a plurality of holes in the corresponding slabs 17, 18, arranged horizontally side by side and in communication with the corresponding channels 20 or 21 present on the other face of the slab. For example, each hole in the plurality may correspond to one of the channels on the other face of the corresponding slab. There may also be screens, filters and/or grids on the slots to prevent foreign elements (dust, excessive humidity, etc.) from entering the internal air circulation circuits.

The would-be lower structure of the panel 16 (with the wall 46 removed for clarity) is also schematically shown as exploded in FIG. 6, while the would-be upper structure of the panel 16 is also schematically shown in FIG. 7.

In particular, both the upper passages 33 communicating with the open upper ends of the second channels 21 and the upper ends of the first channels 20 with the corresponding plugs 30 are clearly visible in FIG. 7.

FIG. 8 shows schematically with arrows the air circulation into the cabinet 10 and through one of the panels 16 as described above and making up the cabinet.

As already mentioned above, in order to create a cabinet 10 one, two or, preferably three walls of the cabinet can advantageously be made with the exchanger panels 16 according to the invention. Fans may also be present to force the desired circulation of air in the two circulation circuits 39 and 42 passing through the panel(s) 16, so as to carry out the desired heat exchange between inside and outside the cabinet. In particular, in the embodiment of the cabinet herein described, it was found advantageous to place fans directly inside the cabinet structure.

Preferably, a first gap 35 in the cabinet is connected to the discharge of a first fan 37 sucking air from inside the cabinet. The fan 37 is advantageously of the centrifugal type.

The first gap 35 is connected to the first slots 28 to send into the first vertical channels 20 the air that is sucked by the first fan 37 and forcedly introduced into the gap 35. The air, after having travelled through the first vertical channels 20, can thus enter back into the internal space of the cabinet through the lower slots 29, located immediately above the internal floor of the cabinet.

The first circulation circuit 39, schematically indicated in FIG. 8 with a continuous-line arrow through one of the panels 16, is thus obtained (circulation through all the panels 16 constituting the cabinet will be similar).

Advantageously, the first gap 35 is located in the ceiling of the internal space of the cabinet and has its periphery directly open against the slots 28 in order to be tightly connected to them and to introduce the air sucked by the fan 37 (fan which is preferably centrally located in the ceiling of the cabinet). Such a fan can advantageously be inserted at least partially within the first gap 35 to have the suction 41 open on an internal ceiling wall of the cabinet and the discharge 43 within the first gap 35.

The cabinet also advantageously comprises a second gap 36 connected to the discharge 44 of a second fan 40 sucking air from outside the cabinet.

Preferably, the second gap 36 extends parallel to and above the first gap 35.

The second gap 36 is connected to the passages 33 on the upper edge of the panel 16 to send the air sucked by the second fan 40 and forcedly introduced into the gap 36. Advantageously, the second fan 40 is inserted at least partially into the gap 36 so that the discharge is directly into the gap. The second fan 40 may preferably be centrally located in the ceiling of the cabinet and above the first fan 37. The two fans can have a vertical rotation axis and can be coaxial with each other.

As it can schematically be seen for example in FIG. 8, each panel 16 used in the cabinet can advantageously have its upper end facing directly into the gap 36 to be easily and directly connected with the air entry passages 33 in the vertical channels 21.

The air passes through the passages 33 along the vertical channels 21, carrying out, through the separating septum 19, the desired heat exchange with the air flowing in the first vertical channels 20, and then leaves the cabinet through the external slots 32. The second circulation circuit 42 is thus created, as schematically indicated in FIG. 8 for a panel 16 by a dotted-line arrow (circulation through all the panels 16 constituting the cabinet will be similar).

Advantageously, the fan 40 sucks air from the external environment through an air intake 38 in a box-shaped cover 45 which is placed on the external roof of the cabinet and which may possibly be provided with suitable known filters, e.g. to prevent dust from being sucked, and which may also be made in a labyrinth shape to prevent rainwater from entering.

The preferred structure for connecting the panels in the upper part of the cabinet in order to have the various desired air passages is also shown schematically in FIGS. 9 and 10.

In FIG. 9, the cover 45 was removed so as to show the underlying sucking fan 40, while in FIG. 10, a conveyor cap 48 making up the external roof of the cabinet and the side and upper walls of the gap 36 were also further removed so as to show the upper passages 33 usually within the gap 36 to let air enter from the gap 36 into the channels 21.

Advantageously, the air circulation fans in the two circulation circuits can also be provided with an electrical or electronic control circuit, schematically indicated with 49 in FIG. 8, to control the activation and/or speed of rotation thereof. Such a control circuit can easily be imagined by the person skilled in the art on the basis of the description given herein. In particular, the circuit 49 may also comprise one or more temperature sensors 50 for measuring the temperature inside the cabinet, so as to activate or make the fans rotate at an appropriate speed depending on the temperature detected by the sensors inside the cabinet, so as to, for example, keep the temperature in the cabinet below a predetermined threshold, while at the same time not unnecessarily activating the fans when not necessary.

The sensors 50 can for example be two, placed one at the bottom and one at the top inside the cabinet so as to at least adjust the speed of the internal circulation fan proportionally to the temperature difference detected by the two sensors. For example, a well-known differential amplifier circuit can be used to detect the temperature difference, as a person skilled in the art can easily imagine.

It is now clear how the pre-set objects were achieved. Despite the simple structure, an optimum heat exchange can be maintained. The cabinet has a high capacity to moderate internal temperature variations, against the dissipation of the equipment installed therein and the variations of the ambient temperature wherein it is installed. Thermal moderation is carried out by the panels according to the invention, which can essentially form the structure of the cabinet itself and can easily be used to form the side and/or rear walls of the cabinet. The heat exchange system thus takes up little space and no space is wasted inside or outside the cabinet.

Advantageously, the internal air is circulated downwards in the panels and the external air is also pumped downwards, thus creating an air-to-air exchanger in a “co-current” configuration.

The hot air, in the upper internal part, has a low density. The contact, through the diaphragm bulkhead in the side panels, of the hot internal air with the cool external air causes the former to cool more quickly and, increasing in density, to descend more rapidly downwards. Air circulation in the cabinet is thereby promoted. This also reduces the power consumption of the internal circulation fan. By means of forced circulation of the internal environment air (with possible dynamic adjustment of the flow rate) through paths and bulkheads created in the side panel(s) (which can themselves be structural elements of the cabinet, as is clear from the description given), the temperature in the lower and upper part of the frame is made uniform. The suction of the external air and its pumping into the external part of the side panel bulkheads allows an effective increase in the specific dissipation of the cabinet. Changing the pumping flow rate of the external air also changes the cooling capacity of the cabinet.

In addition, the internal part of the cabinet has no hydraulic or pneumatic connection to the outside and there is no need for an exchange of air between inside and outside, so that any access of pollutants is avoided. The closing door can easily be made air-tight, as can the entire cabinet structure.

Furthermore, due to the simple structure of the cabinet, the energy required to produce it can be kept relatively low. The required machining of metal parts can also easily be carried out with low-power machinery. For example, metal sheet cutting can be done with simple punching machines and does not require high absorption equipment such as laser cutting systems.

The assembly of the parts composing the cabinet is quick and easy and can be done, for example, by bolting or riveting without using welds.

For example, the supporting structure of the cabinet can easily be made from extruded aluminium profiles, which are connected together by means of bolts or rivets, as a person skilled in the art can easily imagine. No welding is required. The side panels, roof, bottom and frame of the door can be easily attached to the frame by bolting or riveting to slab profiles, which have also been previously secured to the frame by specific bolting or riveting. In this case, bolting can take place within the structure, making as such the panels non-removable if the door is provided with a lock.

With the described structure, an almost or totally recyclable system (even more than 99% of its weight) can be achieved with moderate energy as no special machinery is required.

Clearly, the above description of an embodiment applying the innovative principles of the present invention is given by way of an illustrative example of such innovative principles and must not, therefore, be taken to limit the scope of the patent claimed herein.

For example, if required, the cabinet can easily be made of material (e.g. stainless steel or treated and/or painted metal) suitable for weatherproof outdoor positioning. The special air circulation without air exchange between outside and inside still prevents humidity or environmental pollutants from entering.

The invention claimed is:

1. A cabinet with an internal heat dissipation system, comprising:
walls, at least one of the walls comprising a panel comprising a first slab arranged towards an inside of the cabinet and a second slab arranged towards an outside of the cabinet;
a heat exchange corrugated septum arranged between the first slab and the second slab, the corrugated septum delimiting first air circulation vertical channels between the corrugated septum and the first slab and second air circulation vertical channels between the corrugated septum and the second slab, the first vertical channels being part of a first air circulation circuit circulating air inside the cabinet and the second vertical channels being part of a second air circulation circuit circulating air outside the cabinet.

2. The cabinet according to claim 1, wherein the panel comprises, on the first slab, first upper slots and second lower slots communicating with the first vertical channels adjacently to upper end and lower end respectively of the first vertical channels in the panel, the first slots receiving air from inside the cabinet and the second slots introducing air inside the cabinet to define said first air circulation circuit.

3. The cabinet according to claim 2, wherein the first vertical channels are closed with plugs at the upper and lower ends within the panel.

4. The cabinet according to claim 2, further comprising fans in the first and/or the second circuit for forced air circulation within the cabinet.

5. The cabinet according to claim 4, first comprising a first gap connected to a discharge of a first one of the fans sucking air from inside the cabinet, the first gap being connected to the first slots to send the air sucked by the first one of the fans into the first vertical channels.

6. The cabinet according to claim 5, wherein the first gap is located in a ceiling of the cabinet and has a periphery directly open against the first slots.

7. The cabinet according to claim 5, wherein the first one of the fans is at least partially within the first gap to have a suction open on an interior ceiling wall of the cabinet and a discharge within said first gap (35).

8. The cabinet according to claim 5, wherein the panel comprises, on the second slab, external slots communicating with the lower end of the second vertical channels and passages on an upper edge of the panel, which are in communication with the upper end of the second vertical channels, the passages receiving air from outside the cabinet and the external slots emitting air outside the cabinet to create said second air circulation circuit.

9. The cabinet according to claim 8, further comprising a second gap connected to a discharge of a second one of the fans sucking the air from outside the cabinet, the second gap being connected to the passages on the upper edge of the panel to send the air sucked by the second one of the fans into the second vertical channels.

10. The cabinet according to claim 9, wherein the second gap is located in a ceiling of the cabinet and said passages open directly therein.

11. The cabinet according to claim 9, wherein the second one of the fans is placed on the ceiling of the cabinet in order to have a suction inlet connected to the outside of the cabinet and discharge within the second gap.

12. The cabinet according to claim 9, wherein the second gap extends parallel to and above the first gap.

13. The cabinet according to claim 1, wherein the at least one of the walls is a rear wall of the cabinet.

14. The cabinet according to claim 1, wherein the at least one of the walls comprises at least two side walls of the cabinet.

15. The cabinet according to claim 1, wherein the at least one of the walls comprises are at least two side walls and a rear wall.

16. The cabinet according to claim 4, further comprising temperature measuring sensors inside the cabinet and a control circuit connected to the fans in the first air circulation circuit and/or in the second air circulation circuit, to receive a temperature measurement from said temperature measuring sensors and control said fans according to said temperature measurement.
